(19) United States
(12) Patent Application Publication
(10) Pub. No.: US 2023/0350134 A1
(43) Pub. Date: Nov. 2, 2023

(54) OPTICAL APPARATUS, OPTICAL CONNECTOR, AND METHOD FOR MANUFACTURING OPTICAL APPARATUS

(71) Applicant: SUMITOMO ELECTRIC INDUSTRIES, LTD., Osaka-shi, Osaka (JP)

(72) Inventors: Takuro WATANABE, Osaka-shi (JP); Dai SASAKI, Osaka-shi (JP); Tetsuya NAKANISHI, Osaka-shi (JP); Hajime ARAO, Osaka-shi (JP); Hong Chuyen NGUYEN, Osaka-shi (JP)

(73) Assignee: SUMITOMO ELECTRIC INDUSTRIES, LTD., Osaka-shi, Osaka (JP)

(21) Appl. No.: 17/925,733

(22) PCT Filed: Apr. 6, 2021
(86) PCT No.: PCT/JP2021/014651

§ 371 Date: Nov. 16, 2022

(30) Foreign Application Priority Data
May 26, 2020 (JP) 2020-091208

(51) Int. Cl. G02B 6/36; G02B 6/38

(52) U.S. Cl. CPC G02B 6/3616; G02B 6/381

(57) ABSTRACT

An optical apparatus includes a package, a board, a plurality of first optical cables, and a first optical connector. The package includes an integrated circuit and an optical device that converts an electrical signal from the integrated circuit into an optical signal. The board includes a main surface, and the package is disposed on the main surface. Each of the plurality of first optical cables includes a plurality of optical fibers. Each of the plurality of first optical cables includes a first end portion and a second end portion on a side opposite thereto. Each of a plurality of the first end portions is optically coupled to the optical device, and each of a plurality of the second end portions is attached to the first optical connector. The first optical connector is disposed on the main surface of the board to be entirely located inside an edge of the board.

### TECHNICAL FIELD

The present disclosure relates to an optical apparatus, an optical connector, and a method for manufacturing an optical apparatus. This application is based upon and claims the benefit of priority from Japanese Patent Application No. 2020-091208, filed on May 26, 2020, the entire contents of which are incorporated herein by reference.

### BACKGROUND ART

Patent Literature 1 discloses an optical connector that collectively connects a plurality of optical fiber ribbons to each other. This optical connector is attached, for example, to an edge of a board of a transmission device.

### CITATION LIST

### Patent Literature

[Patent Literature 1] Japanese Unexamined Patent Publication No. H5-119239

### SUMMARY OF INVENTION

As one aspect, the present disclosure provides an optical apparatus. The optical apparatus includes a package, a board, a plurality of first optical cables, and a first optical connector. The package includes an integrated circuit and an optical device configured to convert an electrical signal from the integrated circuit into an optical signal. The board includes a main surface, and the package is disposed on the main surface. Each of the plurality of first optical cables includes a plurality of optical fibers. Each of the plurality of first optical cables includes a first end portion and a second end portion on a side opposite thereto. Each of a plurality of the first end portions is optically coupled to the optical device, and each of a plurality of the second end portions is attached to the first optical connector. The first optical connector is disposed on the main surface of the board to be entirely located inside an edge of the board.

As another aspect, the present disclosure provides an optical connector. The optical connector includes a front housing and a rear housing that is able to be attached to the front housing. The front housing includes a mounting surface. The front housing is provided with a plurality of receiving portions to receive a plurality of ferrules provided at tip end portions of a plurality of optical cables in order in a first direction. The rear housing is provided with a plurality of through holes which extend in a second direction intersecting with the first direction and through which the plurality of optical cables are able to be inserted in order in the first direction. Each of the plurality of through holes of the rear housing has a slit shape that extends along the mounting surface and opens toward a surface of the rear housing.

As another aspect, the present disclosure provides a method for manufacturing an optical apparatus. The method for manufacturing an optical apparatus is a method for manufacturing an optical apparatus by attaching the above-described optical connector to an optical semi-finished product that includes a package including an integrated circuit and an optical device configured to convert an electrical signal from the integrated circuit into an optical signal, a board disposing the package on a main surface thereof, and a plurality of optical cables extending to the outside of the package from the optical device. The method for manufacturing an optical apparatus includes, receiving the plurality of ferrules provided at the tip end portions of the plurality of optical cables in the receiving portions of the front housing, covering intermediate cable portions of the plurality of optical cables extending outward from the package with the plurality of through holes each having the slit shape from above the main surface of the board, and attaching the rear housing to the front housing by relatively moving the rear housing toward the front housing.

### BRIEF DESCRIPTION OF DRAWINGS

FIG. 1 is a perspective view showing an optical apparatus according to an embodiment.

FIG. 2 is a perspective view of the optical apparatus shown in FIG. 1 from a side of a package.

FIG. 3 is a perspective view of the optical apparatus in which a second optical connector is connected to a first optical connector.

FIG. 4 is a perspective view showing a plurality of first optical cables.

FIG. 5 is a perspective view showing a front side of a front housing.

FIG. 6 is a perspective view showing a rear side of the front housing.

FIG. 7 is a perspective view showing a front side of a rear housing.

FIG. 8 is a perspective view showing a rear side of the rear housing.

FIG. 9 is an enlarged view of a part of a cross section of the optical apparatus shown in FIG. 1 along line IX-IX.

FIG. 10 is a flowchart showing a method for manufacturing an optical apparatus.

FIG. 11 is a perspective view showing a first optical cable provided with a spring according to a modification example.

### DESCRIPTION OF EMBODIMENTS

[Problems to be Solved by the Present Disclosure]

When an electrical signal from an integrated circuit such as an application-specific integrated circuit (ASIC) is converted into an optical signal in a communication apparatus or the like, a plurality of internal optical fibers for transmitting the converted optical signal to the outside of the apparatus are collectively connected to a plurality of optical fibers outside the apparatus. For example, an optical connector described in Patent Literature 1 is used for this collective connection. In such a communication apparatus, it is desired to convert an electrical signal from an integrated circuit into an optical signal at a position closer to the integrated circuit as the amount of data communication increases. However, if the optical fibers are simply drawn out from the optical device mounted near the integrated circuit to an edge of the apparatus, since the optical fibers are long, it is difficult to handle the optical fibers when the optical fibers are mounted on the optical device (or the optical device with the optical fibers are mounted). In addition, depending on how the optical fibers are routed, a load may be applied to a connection portion between optical fiber end portions and the optical device or a connection portion between the optical device and the integrated circuit after mounting, and thus misalignment between optical axes and the like may cause connection loss or damage to the connection portion.

[Effects of the Present Disclosure]

According to the present disclosure, as one aspect, it is possible to reduce connection loss when an electrical signal from an integrated circuit is converted into an optical signal and transmitted to the outside.

[Description of Embodiments of the Present Disclosure]

First, the content of embodiments of the present disclosure will be listed and described. An optical apparatus according to an embodiment is provided with a package, a board, a plurality of first optical cables, and a first optical connector. The package includes an integrated circuit and an optical device that converts an electrical signal from the integrated circuit into an optical signal. The board includes a main surface, and the package is disposed on the main surface. Each of the plurality of first optical cables includes a plurality of optical fibers. Each of the plurality of first optical cables includes a first end portion and a second end portion on a side opposite thereto. Each of a plurality of the first end portions is optically coupled to the optical device, and each of a plurality of the second end portions is attached to the first optical connector. The first optical connector is disposed on the main surface of the board to be entirely located inside an edge of the board.

In the optical apparatus, the first optical connector is disposed to be entirely located inside an edge of the board. That is, the first optical connector is located closer to the package than in a case where the first optical connector is disposed such that a part of the first optical connector is located outside the edge of the board. Thus, in the vicinity of the package, it is possible to connect the plurality of first optical cables coupled to the optical device to optical cables drawn out to the outside with the first optical connector. As a result, even in a case where a load is applied to other optical cables drawn out toward the outside of the optical apparatus, the load is received by the first optical connector, and thus it is possible to cause the load not to be transmitted to the plurality of first optical cables coupled to the optical device. Therefore, according to the optical apparatus, it is possible to curb the external load on the plurality of first optical cables connected to the optical device and to reduce connection loss due to misalignment between optical axes. Further, in this optical apparatus, since the first optical connector is provided in the vicinity of the package, when an apparatus such as a communication apparatus on which this optical apparatus is mounted is assembled, it is possible to easily perform a routing work of the optical cable or optical fiber in the apparatus or a connecting work of the optical cable or optical fiber to the optical apparatus. In particular, even in a case where the optical cable or optical fiber used for the routing work or the like is long, they are connected to the first optical connector around the package. Therefore, the work is facilitated, and work efficiency is improved.

As an embodiment of the optical apparatus, the first optical connector may be disposed on the main surface of the board such that a part of the first optical connector is laid on the package and may be fixed to the package directly or with an intervening component. According to this aspect, the first optical connector and the package are disposed very close to each other, and thus it is possible to connect the plurality of first optical cables to optical cables drawn out to the outside at a position closer to the package. Furthermore, since the first optical connector is fixed to the package, it is possible to prevent positional deviation of the first optical connector when the optical fibers are connected to each other.

As an embodiment of the optical apparatus, the first optical connector may include a pair of leg portions to define a region, in which intermediate cable portions extending outward from the package in the plurality of first optical cables aligned along the main surface of the board are disposed, with the package. According to this aspect, an attaching work of the first optical cable or first optical connector can be easily performed using the region, and manufacturing efficiency of the optical apparatus can be improved.

As an embodiment of the optical apparatus, a ferrule may be attached to each of the plurality of second end portions of the plurality of first optical cables, and the first optical connector may include a plurality of receiving portions that align and receive the ferrules. According to this aspect, since each ferrule is received in one of the plurality of receiving portions, the ferrules can be appropriately held without large positional deviation in the first optical connector, and the plurality of first optical cables can be optically connected to the optical cables drawn out to the outside with high accuracy. Moreover, it is possible to prevent damage to the ferrules due to external impact.

As an embodiment of the optical apparatus, the first optical connector may include a front housing that includes the plurality of receiving portions each including a portion configured to restrict forward movement of each ferrule, and a rear housing that includes a portion configured to restrict rearward movement of each ferrule and is attached to the front housing. According to this aspect, since the movement of each ferrule in a front-rear direction is restricted, it is possible to prevent positional deviation of the ferrule when the optical fibers are connected to each other. In addition, since the first optical connector is divided into the front housing that restricts the forward movement of the ferrules and the rear housing that restricts the rearward movement of the ferrules, it is possible to easily attach the first optical cables having the ferrules to the first optical connector.

As an embodiment of the optical apparatus, the rear housing may include a front side and a rear side, and the rear housing may be provided with a plurality of through holes which respectively correspond to the plurality of first optical cables and through which the plurality of first optical cables are respectively inserted from the rear side toward the front side. According to this aspect, since a part of the first optical cable is received in the rear housing, it is possible to prevent the first optical cable from being damaged by an external impact. In addition, since the plurality of first optical cables are inserted into the plurality of through holes, it is possible to prevent contact between the first optical cables or positional deviation of the first optical cable.

As an embodiment of the optical apparatus, each of the plurality of through holes may have a slit shape, and the slit shape may open toward the main surface of the board on which the first optical connector is mounted. According to this aspect, since the through holes have a slit shape, even after the ferrules are received in the front housing, the rear housing can be attached to the front housing to cover the first optical cables from above the main surface.

As an embodiment of the optical apparatus, each of the plurality of through holes may have a cross-sectional area smaller than a cross-sectional area of each of the ferrules and larger than a cross-sectional area of each of the plurality of first optical cables. According to this aspect, since the ferrule cannot pass through the through hole of the rear housing and its movement is restricted, it is possible to prevent the first optical cable from slipping out of the first optical connector.

As an embodiment of the optical apparatus, at least one elastic member configured urge a plurality of the ferrules forward may be provided between the rear housing and the plurality of ferrules.

According to this aspect, the ferrule is urged forward by the elastic member. Therefore, the ferrules are brought into close contact with each other when the optical fibers are connected to each other, and stable optical communication can be performed.

As an embodiment of the optical apparatus, the optical apparatus may further include a plurality of second optical cables each having a plurality of optical fibers, and a second optical connector configured to receive tip end portions of the plurality of second optical cables. The second optical connector is able to be connected to the first optical connector. According to this aspect, the optical apparatus can transmit the optical signal sent from the package through the first optical cable to the outside of the optical apparatus by the second optical cable drawn out to the outside. Further, the optical apparatus uses the plurality of second optical cables whose tip end portions are received in the second optical connector that can be connected to the first optical connector. Therefore, when an apparatus such as a communication apparatus on which this optical apparatus is mounted is assembled, it is possible to further easily perform the routing work of the second optical cables in the apparatus or the connecting work of the second optical cables to the optical apparatus, and it is possible to further improve the work efficiency.

An optical connector according to an embodiment includes a front housing and a rear housing that is able to be attached to the front housing. The front housing includes a mounting surface. The front housing is provided with a plurality of receiving portions to receive a plurality of ferrules provided at tip end portions of a plurality of optical cables in order in a first direction. The rear housing is provided with a plurality of through holes which extend in a second direction intersecting with the first direction and through which the plurality of optical cables are able to be inserted in order in the first direction. Each of the plurality of through holes of the rear housing has a slit shape that opens toward a surface of the housing, the surface extending along the mounting surface.

In this optical connector, the through hole of the rear housing has a slit shape. Thus, when the optical connector is attached in the optical apparatus described above, for example, even after the ferrules are received in the front housing, the rear housing can be attached to the front housing to cover the optical cables from a side surface thereof. Therefore, according to this aspect, it is possible to easily connect tip end portions of the plurality of optical fibers connected to the optical device on the package to the optical connector in the vicinity of the package. Further, since the ferrule and a part of the optical cable are received in the front housing or the rear housing, they are protected from an external impact.

As an embodiment of the optical connector, the front housing may include a main body portion provided with a plurality of receiving holes which are the plurality of receiving portions, and a pair of leg portions extending in the second direction from both ends of the main body portion in the first direction. According to this aspect, by fixing the leg portions of the front housing to the package to which the optical cables are connected, the board on which the package is disposed, or the like, it is possible to prevent positional deviation of the optical connector.

As an embodiment of the optical connector, each of the plurality of receiving portions may include a step that restricts forward movement of each of the ferrules. According to this aspect, the front housing can hold the ferrule at an appropriate position inside the receiving portion. Further, since the configuration is a step, it is possible to simply make the configuration.

As an embodiment of the optical connector, the rear housing may include a plate portion including a front surface and a rear surface, and a plurality of protruding portions that respectively correspond to the plurality of through holes and protrude from the front surface of the plate portion. The plurality of protruding portions may be able to be received in the plurality of receiving portions of the front housing from a rear end thereof. According to this aspect, since the protruding portion of the rear housing is able to be received in the receiving portion of the front housing, it is possible to prevent positional deviation of the rear housing with respect to the front housing and to downsize the optical connector.

As an embodiment of the optical connector, a plurality of elastic members to respectively urge the plurality of ferrules forward may be provided between respective steps in the plurality of receiving portions and the rear housing. According to this aspect, the ferrule is urged forward by the elastic member. Thus, the ferrules are brought into close contact with each other when the optical fibers are connected to each other, and stable optical communication can be performed. Further, each of the plurality of elastic members may include a slit into which one of the optical cables is able to be inserted. According to this aspect, even after the ferrules are received in the front housing, it is possible to easily dispose the elastic member with respect to the optical cable located on the main surface from above the main surface.

A method for manufacturing an optical apparatus according to an embodiment is a method for manufacturing an optical apparatus by attaching the optical connector of any one of the above-described aspects to an optical semi-finished product that includes a package including an integrated circuit and an optical device configured to convert an electrical signal from the integrated circuit into an optical signal, a board disposing the package on a main surface thereof, and a plurality of optical cables extending to the outside of the package from the optical device. This manufacturing method includes receiving the plurality of ferrules provided at the tip end portions of the plurality of optical cables in the receiving portions of the front housing, respectively, covering intermediate cable portions of the plurality of optical cables extending outward from the package with the plurality of through holes each having the slit shape from above the main surface of the board, and attaching the rear housing to the front housing by relatively moving the rear housing toward the front housing.

According to this manufacturing method, it is possible to easily attach the optical connector to the plurality of optical cables extending to the outside of the package from the optical device.

[Details of Embodiments of the Present Disclosure]

Specific examples of an optical apparatus, an optical connector, and a method for manufacturing an optical apparatus according to the embodiments of the present disclosure will be described below with reference to the drawings. The present invention is not limited to these examples, but is defined by the scope of the claims, and is intended to include meanings equivalent to the scope of the claims and all modifications within the scope. In the description of the drawings, the same elements will be denoted by the same reference signs, and duplicate description will be omitted.

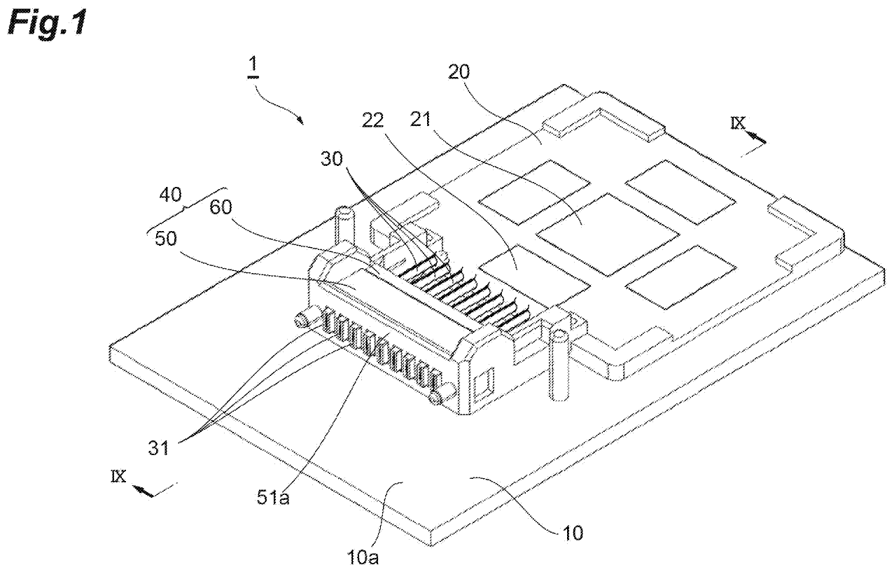

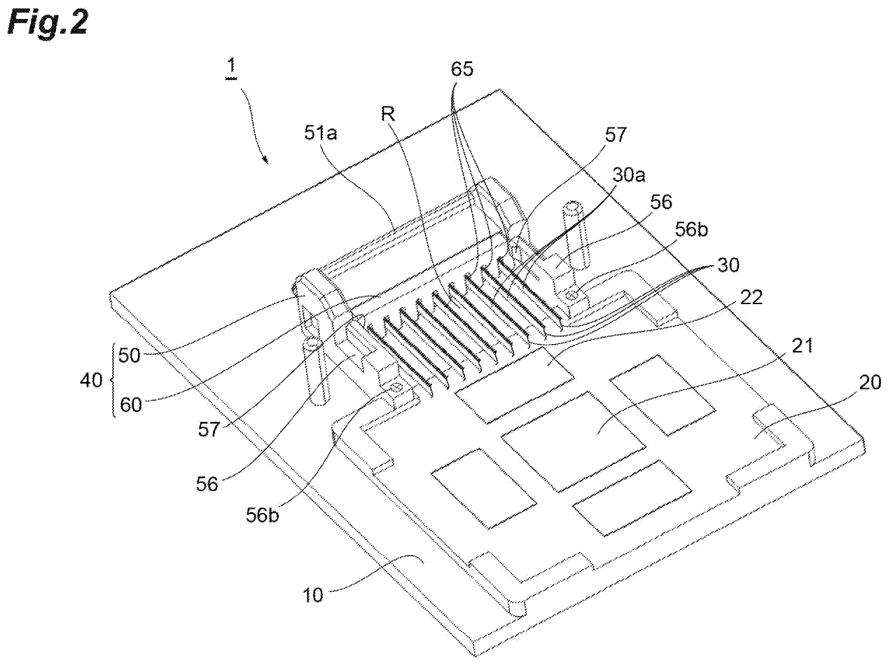

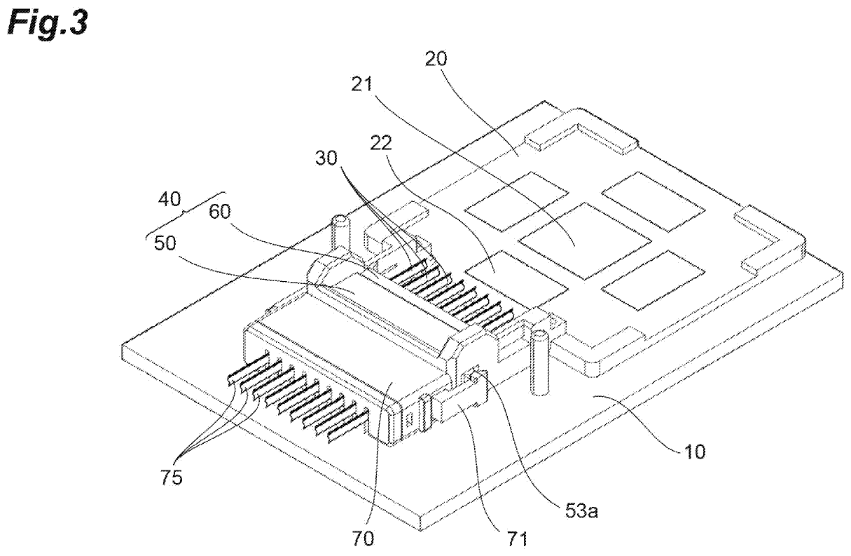

The overall configuration of the optical apparatus 1 will be described with reference to FIGS. 1, 2, and 3. FIG. 1 is a perspective view showing the optical apparatus 1 according to an embodiment. FIG. 2 is a perspective view of the optical apparatus 1 shown in FIG. 1 from a side of a package 20. FIG. 3 is a perspective view of the optical apparatus 1 in which a second optical connector 70 is connected to a first optical connector 40.

As shown in FIGS. 1 and 2, the optical apparatus 1 is an apparatus mounted on an apparatus such as a communication apparatus, and includes a board 10, the package 20, a plurality of first optical cables 30, and the first optical connector 40. The optical apparatus 1 is, for example, an information communication apparatus that transmits optical signals photoelectrically converted by the package 20 to another optical apparatus through the plurality of first optical cables 30. For such transmission, in the optical apparatus 1, for example, the second optical connector 70 is connected to the first optical connector 40, as shown in FIG. 3. The second optical connector 70 has the same configuration as the first optical connector 40, details of which will be described later, and is used to collectively connect a plurality of optical fibers to a plurality of other optical fibers.

The second optical connector 70 is attached to end portions of a plurality of second optical cables 75. The second optical cable 75, like the first optical cable 30, is formed of an optical fiber ribbon having a plurality of optical fibers. A ferrule is attached to a tip end of the second optical cable 75, and the ferrule is received in the second optical connector 70. By the second optical connector 70 being connected to the first optical connector 40, the second optical cables 75 and the first optical cables 30 are optically connected to each other. Latches 71 whose tip ends lock with the first optical connector 40 are provided at both ends of the second optical connector 70. A pair of latches 71 engage the second optical connector 70 with the first optical connector 40. The other end of the second optical cable 75 is connected to another optical apparatus outside or inside an apparatus such as a communication apparatus, for example.

Returning to FIGS. 1 and 2, the description of the optical apparatus 1 will continue. The package 20 is a module placed on a main surface of the board 10 which is a printed circuit board, and includes an integrated circuit 21 and an optical device 22. The integrated circuit 21 is an integrated circuit such as an application-specific integrated circuit (ASIC), for example, and outputs predetermined electrical signals. The optical device 22 is a device that converts electrical signals from the integrated circuit 21 into optical signals. Electrical signals sent out from the integrated circuit 21 are converted into optical signals by the optical device 22 and then is sent out to the plurality of first optical cables 30 optically connected to the optical device 22.

The first optical cable 30 is a cable that transmits optical signals sent from the optical device 22. The first optical cable 30 has a first end portion optically connected to the optical device 22 and a second end portion attached to the first optical connector 40. Although the optical apparatus 1 including eight first optical cables 30 is shown as an example in the present embodiment, the present invention is not limited to this. Although it is sufficient if at least one or more first optical cables 30 are provided, the optical apparatus 1 generally includes a plurality of first optical cables 30.

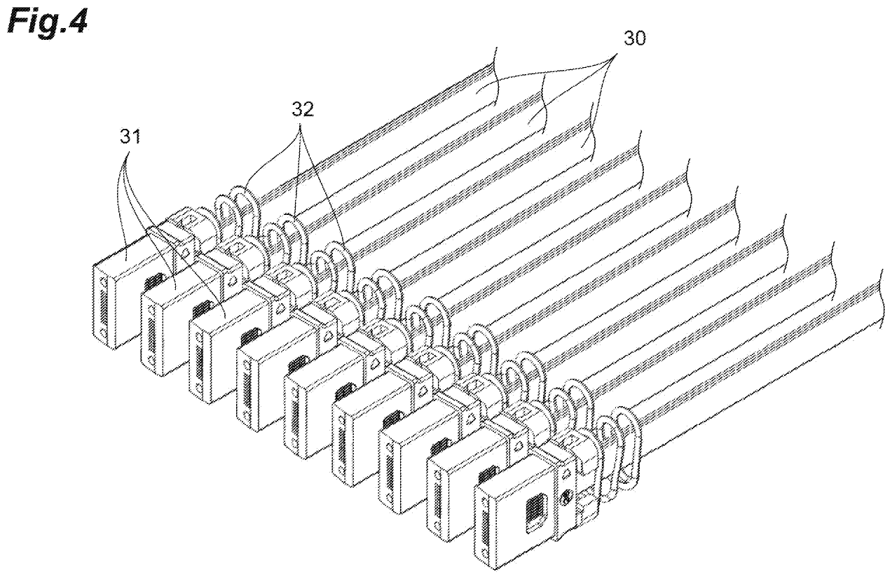

Here, details of the first optical cable 30 will be described with reference to FIG. 4. FIG. 4 is a perspective view showing a plurality of first optical cables 30. Each of the first optical cables 30 is formed of an optical fiber ribbon having a plurality of optical fibers. Each optical fiber ribbon has, for example, 12, 24 (12×2 rows), or 36 (12×3 rows) optical fibers. The optical fiber ribbon is a fiber ribbon in which a plurality of optical fibers are arranged and peripheries thereof are collectively coated with an ultraviolet curable resin. A ferrule 31 is attached to a tip end (the second end portion) of the first optical cable 30.

An end portion of the optical fiber ribbon with a coating thereof peeled off is received in the ferrule 31. The ferrule 31 is, for example, an MT ferrule corresponding to a multifiber-type optical fiber ribbon.

A spring 32 is wound around the first optical cable 30 as an elastic member. The spring 32 is attached in advance so that the first optical cable 30 passes through the spring 32 from an end portion of the first optical cable 30 to which the ferrule 31 is not attached. The elastic member disposed around the first optical cable 30 is not limited to the spring 32 and may be an arbitrary elastic member such as rubber. At this time, the elastic member may be provided with a through hole through which the first optical cable 30 can be inserted. In a state where the optical apparatus 1 is assembled, the spring 32 is located between the ferrule 31 and a rear housing 60, which will be described later, and urges the ferrule 31 forward.

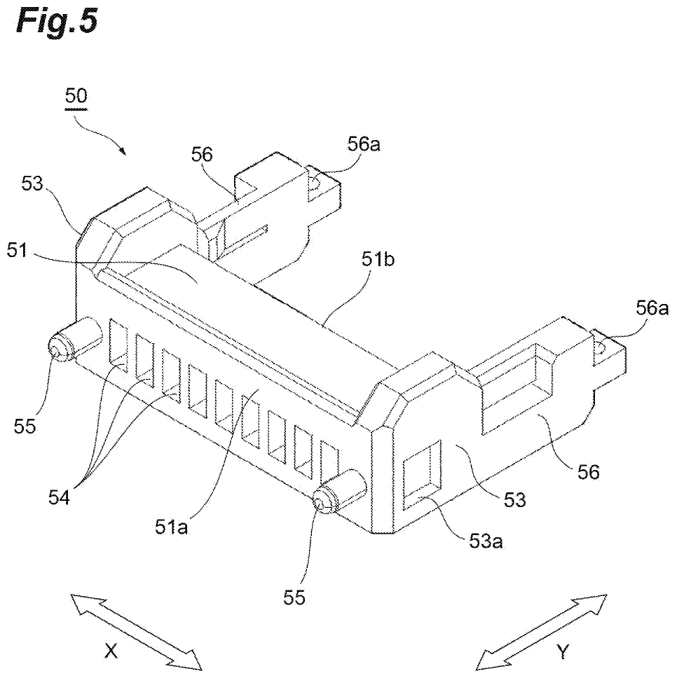

Returning to FIGS. 1 and 2, the description of the optical apparatus 1 will continue. The first optical connector 40 is disposed on the board 10 of the optical apparatus 1. The first optical connector 40 is used to collectively connect a plurality of optical fibers to a plurality of other optical fibers. The first optical connector 40 includes a front housing 50 and a rear housing 60. Details of the front housing 50 and the rear housing 60 will now be described with reference to FIGS. 5 to 8.

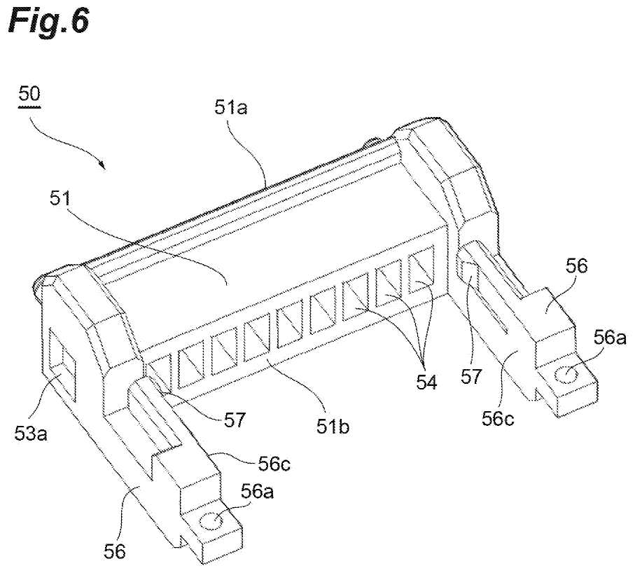

FIG. 5 is a perspective view showing a side of a front end surface 51a of the front housing 50. FIG. 6 is a perspective view showing a side of a rear end surface 51b of the front housing 50. The front housing 50 is a component that couples with the second optical connector 70 that is a counterpart when the optical fibers are connected to each other (see FIG. 3). The front housing 50 includes a main body portion 51 provided with a plurality of receiving portions 54 in which the ferrules 31 are received, and a pair of leg portions 56 extending from both ends of the main body portion 51.

The main body portion 51 has a front end face 51a, which is a surface facing the second optical connector 70 when the optical fibers are connected to each other, and a rear end surface 51b located on a side opposite to the front end surface 51a. The main body portion 51 has two side surfaces 53 formed from both end portions of the front end surface 51a toward the rear end surface 51b.

The main body portion 51 has the plurality of receiving portions 54 that align and receive the ferrules 31. Each of the receiving portions 54 is a through hole (a receiving hole) formed to pass through the main body portion from the front end surface 51a toward the rear end surface 51b. The plurality of receiving portions 54 are provided in order in a first direction (a direction of arrow X in FIG. 5) extending between the two side surfaces 53 of the front housing 50. The number of receiving portions 54 corresponds to the number of first optical cables 30.

The pair of leg portions 56 that extend in a second direction (a direction of arrow Y in FIG. 5) extending between the front end surface 51a and the rear end surface 51b are formed at both ends of the main body portion 51. As shown in FIG. 2, in a state where the front housing 50 is disposed on the main surface of the board 10, tip ends of the pair of leg portions 56 are located to be laid on a peripheral edge of the package 20. The first optical cables 30 extending outward from the package 20 are disposed in a defined region R defined by the package 20 and the pair of leg portions 56 (a region surrounded by the package 20 and the pair of leg portions 56). A portion of the first optical cable 30 located within the defined region R is referred to as an intermediate cable portion 30a.

The pair of leg portions 56 are fixed to the package 20 directly or with intervening components. In the present embodiment, as shown in FIG. 6, a screw hole 56a is provided at each of the tip ends of the pair of leg portions 56. The pair of leg portions 56 are fixed to the package 20 by each screw 56b being inserted into each screw hole 56a and being screwed to the package 20. The pair of leg portions 56 may be fixed to the package 20 or the board 10 by attachment means (for example, an adhesive and the like) other than the screw.

An inner wall 56c of each leg portion 56 is provided with a locking portion 57 that locks with the rear housing 60. Each locking portion 57 has a shape protruding toward the inside of the front housing 50. The rear housing 60, which will be described later, is attached to the front housing 50 to be sandwiched between the rear end surface 51b and both locking portions 57 of the front housing 50.

A recess 53a is formed in each of the side surfaces 53 of the main body portion 51. When the first optical connector 40 and the second optical connector 70 are connected to each other, the tip ends of the pair of latches 71 of the second optical connector 70 lock with the corresponding recesses 53a, and the second optical connector 70 is fixed to the first optical connector 40 (see FIG. 3).

A pair of protrusions 55 are formed on the front end surface 51a of the main body portion 51. The pair of protrusions 55 are used for alignment when the first optical connector 40 and the second optical connector 70 are connected to each other. Specifically, the pair of protrusions 55 are shaped to protrude forward in a connecting direction of the optical fibers, and the pair of protrusions 55 are inserted into recesses provided on a front end surface of the second optical connector 70, thereby causing alignment to be performed.

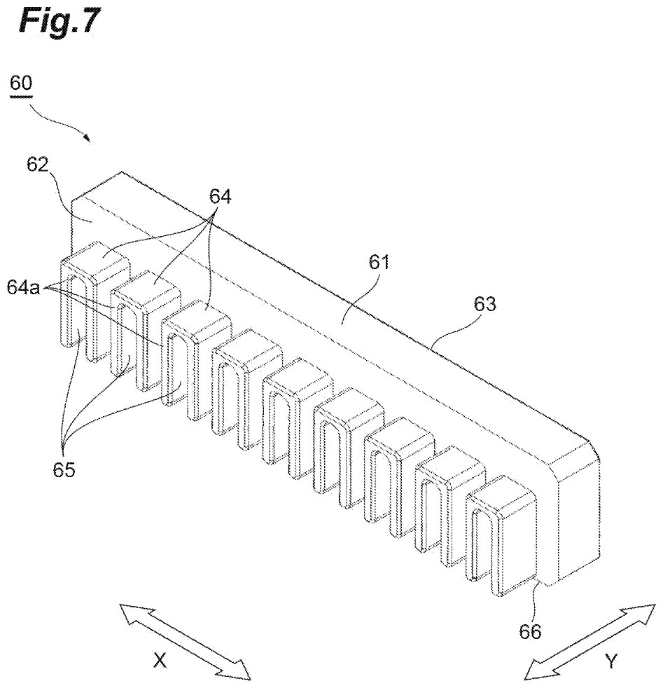

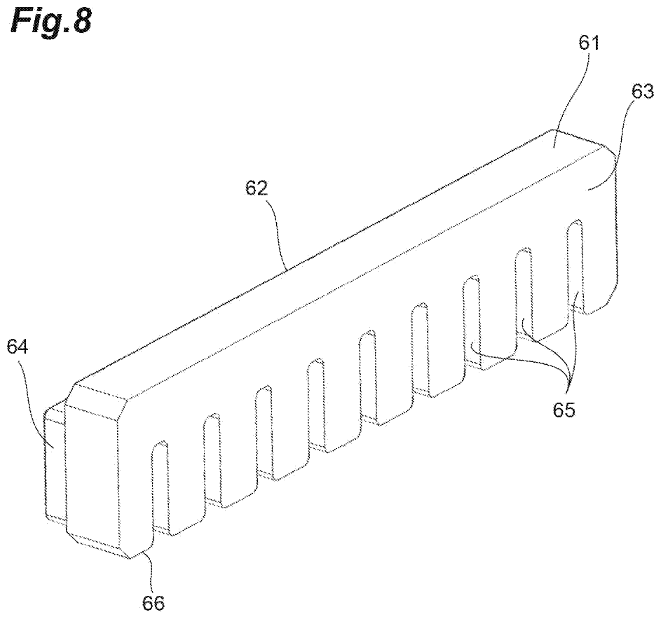

Next, details of the rear housing 60 will be described with reference to FIGS. 7 and 8. FIG. 7 is a perspective view showing a side of a front surface 62 of the rear housing 60. FIG. 8 is a perspective view showing a side of a rear surface 63 of the rear housing 60. The rear housing 60 is a component that constitutes the first optical connector 40 together with the front housing 50 and is attached to a side of the rear end surface 51b of the main body portion 51.

The rear housing 60 has a plate portion 61 and a plurality of protruding portions 64, as shown in FIGS. 7 and 8. The plate portion 61 has a flat, substantially rectangular parallelepiped shape and has the front surface 62 and the rear surface 63 facing the front surface 62. The plurality of protruding portions 64 are formed on the front surface 62. The protruding portions 64 are provided in order in the first direction (a direction of arrow X in FIG. 7) extending between both ends of the rear housing 60. Each of the plurality of protruding portions 64 is formed with a size that allows the protruding portion to be received in the corresponding receiving portion 54 of the main body portion 51. The number of protruding portions 64 provided in the rear housing 60 corresponds to the number of receiving portions 54 provided in the main body portion 51.

The plate portion 61 and the plurality of protruding portions 64 of the rear housing 60 include a plurality of through holes 65 through which the plurality of first optical cables 30 can be inserted in order in the first direction. The through hole 65 is formed such that the rear surface 63 of the plate portion 61 and a tip end surface 64a of the protruding portion 64 communicate with each other. The through hole 65 has a slit shape, and the rear housing 60 is disposed such that the slit shape opens toward the main surface of the board 10 (see FIG. 2). That is, the slit shape opens at a lower surface 66 of the rear housing 60. The number of through holes 65 formed in the rear housing 60 corresponds to the number of first optical cables 30.

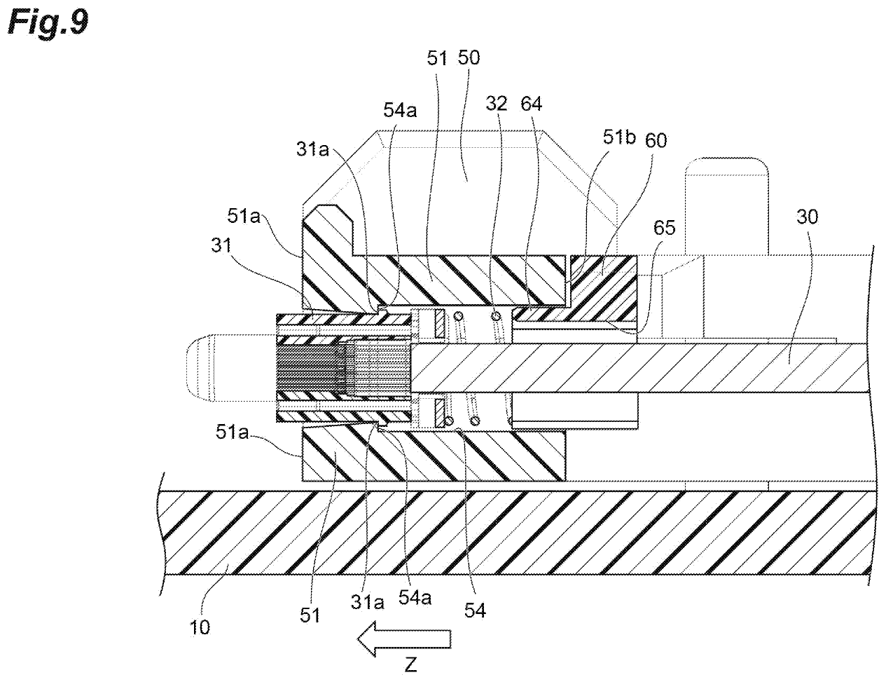

FIG. 9 is an enlarged view of a part of a cross section of the optical apparatus 1 shown in FIG. 1 along line IX-IX. An internal structure of the first optical connector 40 will be described with reference to FIG. 9. As shown in FIG. 9, the ferrule 31 is received in the receiving portion 54 of the main body portion 51. The rear housing 60 is attached to the rear end surface 51b of the main body portion 51. The protruding portion 64 of the rear housing 60 is inserted into the receiving portion 54 from an opening of the receiving portion 54 at the rear end surface 5 lb. The spring 32 is located between the ferrule 31 and the protruding portion 64.

The ferrule 31 is urged forward (in a direction of arrow Z in FIG. 9) by an elastic force of the spring 32.

A first step 54a is formed on an inner wall of the receiving portion 54 of the main body portion 51. On the other hand, a second step 31a that comes into contact with the first step 54a is formed on an outer wall of the ferrule 31 received in the receiving portion 54. Even in a case where the ferrule 31 is moved forward by a urging force of the spring 32, forward movement of the ferrule 31 is restricted at a predetermined position by the contact of the second step 31a with the first step 54a.

The through hole 65 of the rear housing 60 has a cross-sectional area smaller than a cross-sectional area of each of the ferrule 31 and the spring 32 and larger than a cross-sectional area of the first optical cable 30. Thus, even in a case where the ferrule 31 moves excessively rearward, the ferrule 31 cannot pass through the through hole 65 and stops at a predetermined position. That is, rearward movement of the ferrule 31 is restricted by the rear housing 60. The “cross-sectional area” referred to here is not an area of a cross section shown in FIG. 9, but an area relating to a cross section in a direction perpendicular to an extending direction of the first optical cable 30.

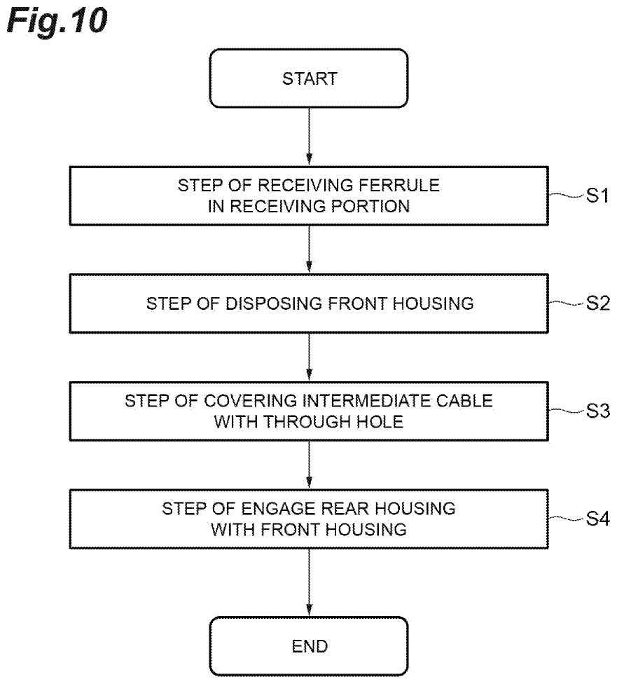

Here, a method for manufacturing the optical apparatus 1 by attaching the above-described first optical connector 40 to an optical semi-finished product having the board 10 on which the package 20 is disposed on the main surface will be described with reference to FIG. 10. FIG. 10 is a flowchart showing a method for manufacturing the optical apparatus 1.

First, each ferrule 31 provided at each tip end (the second end portion) of the plurality of first optical cables 30 extending from the package 20 is received in the corresponding receiving portion 54 of the front housing 50 (Step S1). Specifically, each ferrule 31 is inserted into the receiving portion 54 from the opening, which is located on the rear end surface 51b of the main body portion 51, of the receiving portion 54 and is received in the receiving portion 54 such that the tip end of the ferrule 31 slightly protrudes from an opening, which is located on the front end surface 51a, of the through hole 65.

Next, the front housing 50 is disposed on the main surface of the board 10 (Step S2). At this time, as shown in FIG. 1, the front housing 50 is disposed adjacent to the package 20 such that the front housing 50 is entirely located inside an edge of the board 10. As shown in FIG. 2, the pair of leg portions 56 of the front housing 50 are disposed such that the tip ends thereof are laid on the peripheral edge of the package 20. After that, the screws 56b are attached to the screw holes 56a provided in the pair of leg portions 56, and the front housing 50 is fixed to the package 20. The mounting of the front housing 50 on the board 10 in Step S2 may be performed before the ferrule is received in Step S1.

Next, the intermediate cables located in the defined region defined by the package 20 and the pair of leg portions 56 are covered with the through holes 65 of the rear housing 60 (Step S3). Specifically, the through holes 65, which each have the slit shape, of the rear housing 60 cover the intermediate cables disposed on the main surface from above the main surface, and a part of each of the intermediate cables is received in the slit. In other words, the rear housing 60 is disposed such that a portion in which the through holes 65 are not formed slides between the adjacent intermediate cables.

Finally, the rear housing 60 is relatively moved toward the front housing 50 to engage the rear housing 60 with the front housing 50 (Step S4). Specifically, the rear housing 60 located on the intermediate cables is slid toward the rear end surface 51b of the front housing 50. At this time, both ends of the rear housing 60 come into contact with the locking portions 57 formed on the inner walls of the leg portions 56, and the rear housing 60 is prevented from moving. However, since surfaces of the locking portions 57 that come into contact with the rear housing 60 are inclined with respect to the inner walls of the leg portions 56, when the rear housing 60 is pushed toward the front housing 50, the locking portions 57 are spread outward by both ends of the rear housing 60. Thus, the rear housing 60 can be disposed between the rear end surface 51b of the front housing 50 and the locking portions 57 beyond the locking portions 57 (see FIG. 2). The disposed rear housing 60 is locked by the locking portions 57. At this time, the protruding portion 64 of the rear housing 60 is inserted into the receiving portion 54 from the opening of the receiving portion 54 and comes into contact with the spring 32 wound around the first optical cable 30. As described above, the attachment of the first optical connector 40 is completed, and a manufacturing process of the optical apparatus 1 is completed.

As described above, according to the optical apparatus 1 of the present embodiment, the first optical connector 40 is disposed to be entirely located inside the edge of the board 10. That is, the first optical connector 40 is located closer to the package 20 than in a case where the first optical connector 40 is disposed such that a part of the first optical connector 40 is located outside the edge of the board 10. Thus, in the vicinity of the package 20, it is possible to connect the plurality of first optical cables 30 coupled to the optical device 22 to the second optical cables 75 drawn out to the outside with the first optical connector 40. As a result, even in a case where a load is applied to the second optical cables 75 drawn out toward the outside of the optical apparatus 1, the load is received by the first optical connector 40, and thus it is possible to cause the load not to be transmitted to the plurality of first optical cables 30 coupled to the optical device 22. Therefore, according to the optical apparatus 1, it is possible to curb the external load on the plurality of first optical cables 30 connected to the optical device 22 and to reduce connection loss due to misalignment between optical axes. Further, in the optical apparatus 1, since the first optical connector 40 is provided in the vicinity of the package 20, when an apparatus such as a communication apparatus on which the optical apparatus 1 is mounted is assembled, it is possible to easily perform a routing work of the optical cable or optical fiber in the apparatus or a connecting work of the optical cable or optical fiber to the optical apparatus 1. In particular, even in a case where the optical cable or optical fiber used for the routing work or the like is long, they are connected to the first optical connector 40 around the package 20. Therefore, the work is facilitated, and work efficiency is improved.

The first optical connector 40 is disposed on the main surface 10a of the board 10 such that a part of the first optical connector 40 is laid on the package 20. Therefore, the first optical connector 40 and the package 20 are disposed very close to each other, and thus it is possible to connect the optical fibers to each other at a position closer to the package 20. Furthermore, since the first optical connector 40 is fixed to the package 20 directly or with the intervening component, it is possible to prevent positional deviation of the first optical connector 40 when the optical fibers are connected to each other.

In the optical apparatus 1, the first optical connector 40 has the pair of leg portions 56 to define a region, in which the intermediate cable portions extending outward from the package 20 in the plurality of first optical cables 30 aligned along the main surface 10a of the board 10 are disposed, with the package 20. Therefore, an attaching work of the first optical cables 30 or first optical connector 40 can be easily performed using the region, and manufacturing efficiency of the optical apparatus 1 can be improved.

In the optical apparatus 1, each ferrule 31 is received in each of the plurality of receiving portions 54. Therefore, the ferrules 31 can be appropriately held without large positional deviation in the first optical connector 40, and the plurality of first optical cables 30 can be optically connected to the second optical cables 75 drawn out to the outside with high accuracy. Moreover, it is possible to prevent damage to the ferrules 31 due to external impact or contact between the ferrules 31.

In the optical apparatus 1, the front housing 50 has the first step 54a that restricts the forward movement of each ferrule 31, and the rear housing 60 has the protruding portion 64 that restricts the rearward movement of each ferrule 31. In this way, in the optical apparatus 1, since the movement of each ferrule 31 in a front-rear direction is restricted, it is possible to prevent positional deviation of the ferrule 31 when the optical fibers are connected to each other. In addition, since the first optical connector 40 is divided into the front housing 50 that restricts the forward movement of the ferrules 31 and the rear housing 60 that restricts the rearward movement of the ferrules 31, it is possible to easily attach the plurality of first optical cables 30 having the ferrules to the first optical connector 40.

In the optical apparatus 1, each of the plurality of protruding portions 64 of the rear housing 60 can be received in the corresponding receiving portion 54 of the front housing 50 from a rear end thereof. Therefore, it is possible to prevent positional deviation of the rear housing 60 with respect to the front housing 50 and to downsize the first optical connector 40. Further, it is possible to reduce a distance between the ferrule 31 received in each receiving portion 54 and each protruding portion 64 of the rear housing 60 and to downsize the spring 32 disposed therebetween.

In the optical apparatus 1, the rear housing 60 has the plurality of through holes 65 through which the plurality of first optical cables 30 are inserted. Therefore, a part of the first optical cable 30 is received in the rear housing 60, and it is possible to prevent the first optical cable 30 from being damaged by an external impact. In addition, since the plurality of first optical cables 30 are inserted into the plurality of through holes 65, it is possible to prevent contact between the first optical cables 30 or positional deviation of the first optical cable 30. Furthermore, each through hole 65 has the slit shape that opens toward the main surface 10a of the board 10. Therefore, even after the ferrules 31 are received in the front housing 50, the rear housing 60 can be attached to the front housing 50 to cover the first optical cables 30 from above the main surface.

Furthermore, each of the plurality of through hole 65 has a cross-sectional area smaller than a cross-sectional area of each of the ferrule 31 and the spring 32, and larger than a cross-sectional area of the first optical cable 30. Therefore, since the ferrule 31 cannot pass through the through hole 65 and its movement is restricted, it is possible to prevent the first optical cable 30 from slipping out of the rear housing 60.

In the optical apparatus 1, the ferrule 31 is urged forward by the elastic member (the spring 32). Therefore, the ferrules are brought into close contact with each other when the optical fibers are connected to each other, and stable optical communication can be performed.

The optical apparatus 1 includes the plurality of second optical cables 75 and the second optical connector 70 attached to the tip ends of the second optical cables 75. Therefore, the optical apparatus 1 can transmit the optical signals sent from the package 20 to an external optical apparatus through the first optical cables 30 and the second optical cables 75 by the first optical connector 40 and the second optical connector 70 being connected to each other. Further, the optical apparatus 1 uses the plurality of second optical cables 75 whose tip end portions are received in the second optical connector 70 that can be connected to the first optical connector 40. Therefore, when an apparatus such as a communication apparatus on which the optical apparatus 1 is mounted is assembled, it is possible to further easily perform the routing work of the second optical cables 75 in the apparatus or the connecting work of the second optical cables 75 to the optical apparatus 1, and it is possible to further improve the work efficiency.

Although the embodiment of the present invention is described in detail above, the present invention is not limited to the above embodiment and can be applied to various embodiments.

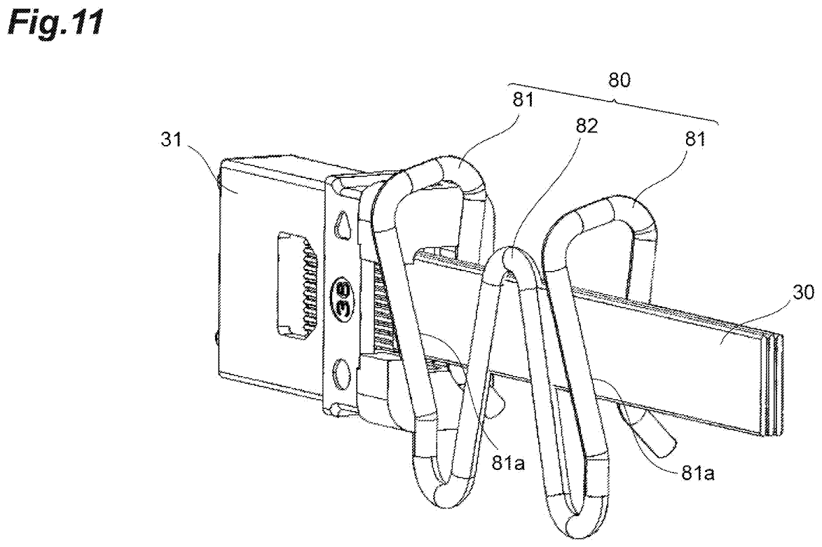

For example, the shape and arrangement of the spring 32 that urges the ferrule 31 forward are not limited to those described above. For example, a spring 80 configured as shown in FIG. 11 can be used as the elastic member that urges the ferrule 31 forward. FIG. 11 is a perspective view showing a first optical cable 30 provided with a spring 80 according to a modification example. Although FIG. 11 shows an application example to one first optical cable 30 as an example, the spring 80 according to the modification example may be applied to all the first optical cables 30 used in the optical apparatus 1. The spring 80 has a pair of hook portions 81 and an elastic portion 82, as shown in FIG. 11. Each hook portion 81 is a portion configured to cover the first optical cable 30 from above and has a slit portion 81a that opens toward the main surface 10a of the board 10. Apart of the first optical cable 30 is housed inside the each slit portion 81a from an opening thereof. The elastic portion 82 is a member that connects the hook portions 81 to each other and expands and contracts in the same direction as the extending direction of the first optical cable 30. The elastic portion 82 is a metal wire bent into a mountain shape on one side of the first optical cable 30 and provides an urging force. The pair of hook portions 81 and the elastic portion 82 are integrally formed of, for example, the same material. Thus, in a case where the spring 80 having the slit portion 81a and the elastic portion 82 formed only on one side is used as the elastic member, even after the ferrule 31 is received in the front housing 50, it is possible to easily dispose the spring 80 with respect to the first optical cable 30 located on the main surface 10a from above the main surface 10a. That is, the spring 80 can be easily installed.

In addition, the spring 80 according to the modification example is configured to independently correspond to one first optical cable 30, but as the elastic member that urges the ferrule 31 forward, a plurality of springs 80 may be integrated into a single continuous member over the plurality of first optical cables 30. By forming the elastic member to be one member over the plurality of first optical cables 30, it is possible to reduce the number of works for attaching the springs 80 during manufacturing of the optical apparatus 1, and it is possible to improve manufacturing efficiency of the optical apparatus 1. A urging means for the ferrule 31 is not limited to the springs 32 and 80, and may be an elastic member obtained by forming a slit portion in an elastic body such as rubber.

Further, the front housing 50 and the rear housing 60 may be integrally formed of the same member. In this case, the receiving portion 54 of the front housing 50 may have a slit shape that opens toward the main surface 10a of the board 10. Accordingly, the entire first optical connector 40 can be disposed to cover the first optical cables 30 disposed on the main surface.

### REFERENCE SIGNS LIST

1 Optical apparatus

10 Board

10a Main surface

20 Package

21 Integrated circuit

22 Optical device 30 First optical cable

30a Intermediate cable portion

31 Ferrule

31a Second step

32 Spring

40 First optical connector

50 Front housing

51 Main body portion

51a Front end surface

51b Rear end surface

53 Side surface

53a Recess

54 Receiving portion

54a First step

55 Protrusion

56 Leg portion

56a Screw hole

56b Screw

56c Inner wall

57 Locking portion

60 Rear housing

61 Plate portion

62 Front surface

63 Rear surface

64 Protruding portion

64a Tip end surface

65 Through hole

66 Lower surface

70 Second optical connector

71 Latch

75 Second optical cable

80 Spring

81 Hook portion

81a Slit portion

82 Elastic portion

1. An optical apparatus comprising:
a package including an integrated circuit and an optical device configured to convert an electrical signal from the integrated circuit into an optical signal;
a board including a main surface, the package being disposed on the main surface;
a plurality of first optical cables each including a plurality of optical fibers, each of the plurality of first optical cables including a first end portion and a second end portion on a side opposite thereto, and each of a plurality of the first end portions being optically coupled to the optical device; and
a first optical connector to which each of a plurality of the second end portions of the plurality of first optical cables is attached,
wherein the first optical connector is disposed on the main surface of the board to be entirely located inside an edge of the board.

2. The optical apparatus according to claim 1, wherein the first optical connector is disposed on the main surface of the board such that a part of the first optical connector is laid on the package, and is fixed to the package directly or with an intervening component.

3. The optical apparatus according to claim 1, wherein the first optical connector includes a pair of leg portions to define a region, in which intermediate cable portions extending outward from the package in the plurality of first optical cables aligned along the main surface of the board are disposed, with the package.

4. The optical apparatus according to claim 1,
wherein a ferrule is attached to each of the plurality of second end portions of the plurality of first optical cables, and
wherein the first optical connector includes a plurality of receiving portions that align and receive the ferrules.

5. The optical apparatus according to claim 4, wherein the first optical connector includes
a front housing that comprises the plurality of receiving portions each including a portion configured to restrict forward movement of each ferrule, and
a rear housing that comprises a portion configured to restrict rearward movement of each ferrule and is attached to the front housing.

6. The optical apparatus according to claim 5,
wherein the rear housing includes a front side and a rear side, and
wherein the rear housing is provided with a plurality of through holes which respectively correspond to the plurality of first optical cables and through which the plurality of first optical cables are respectively inserted from the rear side toward the front side.

7. The optical apparatus according to claim 6, wherein each of the plurality of through holes has a slit shape, and the slit shape opens toward the main surface of the board on which the first optical connector is mounted.

8. The optical apparatus according to claim 6, wherein each of the plurality of through holes has a cross-sectional area smaller than a cross-sectional area of each of the ferrules and larger than a cross-sectional area of each of the plurality of first optical cables.

9. The optical apparatus according to claim 5, wherein at least one elastic member configured to urge a plurality of the ferrules forward is provided between the rear housing and the plurality of ferrules.

10. The optical apparatus according to claim 1, further comprising:
a plurality of second optical cables each including a plurality of optical fibers; and
a second optical connector configured to receive tip end portions of the plurality of second optical cables and being able to be connected to the first optical connector.

11. An optical connector comprising:
a front housing including a mounting surface and provided with a plurality of receiving portions to receive a plurality of ferrules provided at tip end portions of a plurality of optical cables in order in a first direction; and
a rear housing provided with a plurality of through holes which extend in a second direction intersecting with the first direction and through which the plurality of optical cables are able to be inserted in order in the first direction, the rear housing being able to be attached to the front housing,
wherein each of the plurality of through holes has a slit shape that opens toward a surface of the rear housing, the surface extending along the mounting surface.

12. The optical connector according to claim 11, wherein the front housing includes
a main body portion provided with a plurality of receiving holes which are the plurality of receiving portions, and
a pair of leg portions extending in the second direction from both ends of the main body portion in the first direction.

13. The optical connector according to claim 11, wherein each of the plurality of receiving portions includes a step that restricts forward movement of each of the ferrules.

14. The optical connector according to claim 11,
wherein the rear housing includes
a plate portion including a front surface and a rear surface, and
a plurality of protruding portions that respectively correspond to the plurality of through holes and protrude from the front surface of the plate portion,
wherein the plurality of protruding portions are able to be received in the plurality of receiving portions of the front housing from a rear end thereof.

15. The optical connector according to claim 11,
wherein a plurality of elastic members to respectively urge the plurality of ferrules forward are provided between respective steps in the plurality of receiving portions and the rear housing, and
wherein each of the plurality of elastic members includes a slit into which one of the optical cables is able to be inserted.

16. A method for manufacturing an optical apparatus by attaching the optical connector according to claim 11 to an optical semi-finished product that includes a package including an integrated circuit and an optical device configured to convert an electrical signal from the integrated circuit into an optical signal, a board disposing the package on a main surface thereof, and a plurality of optical cables extending to the outside of the package from the optical device, the method comprising:
receiving the plurality of ferrules provided at the tip end portions of the plurality of optical cables in the receiving portions of the front housing;
covering intermediate cable portions of the plurality of optical cables extending outward from the package with the plurality of through holes each having the slit shape from above the main surface of the board; and
attaching the rear housing to the front housing by relatively moving the rear housing toward the front housing.
